(19) United States
(12) Patent Application Publication
(10) Pub. No.: US 2024/0014093 A1
(43) Pub. Date: Jan. 11, 2024

(54) Semiconductor Device and Method of Heat Dissipation Using Graphene

(71) Applicant: STATS ChipPAC Pte. Ltd., Singapore (SG)

(72) Inventors: ChangOh Kim, Incheon (KR); JinHee Jung, Incheon (KR); OMin Kwon, Incheon (KR); HeeSoo Lee, Incheon (KR)

(73) Assignee: STATS ChipPAC Pte. Ltd., Singapore (SG)

(21) Appl. No.: 17/810,901

(22) Filed: Jul. 6, 2022

(51) Int. Cl. H01L 23/367; H01L 23/373; H01L 23/433

(52) U.S. Cl. CPC H01L 23/3672; H01L 23/373; H01L 23/4334

(57) ABSTRACT

A semiconductor device has a first substrate and electrical component disposed over the first substrate. A graphene layer is disposed over the electrical component, and a thermal interface material is disposed between the graphene layer. A heat sink is disposed over the thermal interface material. The graphene layer, in combination with the thermal interface material, aids with the heat transfer between the electrical component and heat sink. The graphene layer may be disposed over a second substrate made of copper. An encapsulant is deposited over the first substrate and around the electrical component and graphene substrate. The thermal interface material and heat sink may extend over the encapsulant. The heat sink can have vertical or angled extensions from the horizontal portion of the heat sink down to the substrate. The heat sink can extend over multiple modules.

### FIELD OF THE INVENTION

The present invention relates in general to semiconductor devices and, more particularly, to a semiconductor device and method of heat dissipation using graphene.

### BACKGROUND OF THE INVENTION

Semiconductor devices are commonly found in modern electronic products. Semiconductor devices perform a wide range of functions, such as signal processing, high-speed calculations, transmitting and receiving electromagnetic signals, controlling electronic devices, photo-electric, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Semiconductor devices, particularly in high frequency applications, such as radio frequency (RF) wireless communications, often contain one or more integrated passive devices (IPDs) to perform necessary electrical functions. Multiple semiconductor die and IPDs can be integrated into an SiP module for higher density in a small space and extended electrical functionality. Within the SIP module, semiconductor die and IPDs are disposed on a substrate for structural support and electrical interconnect. An encapsulant is deposited over the semiconductor die, IPDs, and substrate. A conformal electromagnetic interference (EMI) shielding layer is commonly formed over the encapsulant.

The SIP module includes high speed digital and RF electrical components, highly integrated for small size and low height, and operating at high clock frequencies and high power rating. The electrical components are known to generate substantial heat, which must be properly dissipated.

Copper, which is widely used for the conformal EMI shielding, has high thermal conductivity of about 400 W m⁻¹ K⁻¹. Conformal EMI shielding can be used for heat dissipation material. However, since the conformal shielding structure is SUS/Cu/SUS, it is difficult to attach a heat sink material on the surface of SUS due to low solderability and wettability of solder paste on SUS surface. Copper is good material to solderability and wettability of solder paste but copper is easy to oxidize without SUS layer in EMI shielding layer structures (SUS/Cu/SUS). A need still exists to improve heat dissipation, particularly in applications involving high speed digital and RF electrical components.

### BRIEF DESCRIPTION OF THE DRAWINGS

FIGS. 1a-1c illustrate a semiconductor wafer with a plurality of semiconductor die separated by a saw street;

FIGS. 2a-2g illustrate a process of forming a graphene substrate;

FIGS. 3a-3b illustrate a CVD process of forming a graphene wafer;

FIGS. 4a-4c illustrate another process of forming a graphene substrate;

FIGS. 5a-5f illustrate forming a graphene substrate, TIM, and heat sink over an SiP module;

FIGS. 6a-6d illustrate another embodiment of forming a graphene substrate, TIM, and heat sink over an SiP module;

FIGS. 7a-7c illustrate another embodiment of forming a graphene substrate, TIM, and heat sink over an SiP module;

FIGS. 8a-8c illustrate another embodiment of forming a graphene substrate, TIM, and heat sink over an SiP module;

FIG. 9 illustrates a heat sink with vertical extensions to the substrate;

FIG. 10 illustrates a heat sink with angled extensions to the substrate;

FIG. 11 illustrates a heat sink over multiple SiP modules; and

FIG. 12 illustrates a printed circuit board (PCB) with different types of packages disposed on a surface of the PCB.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

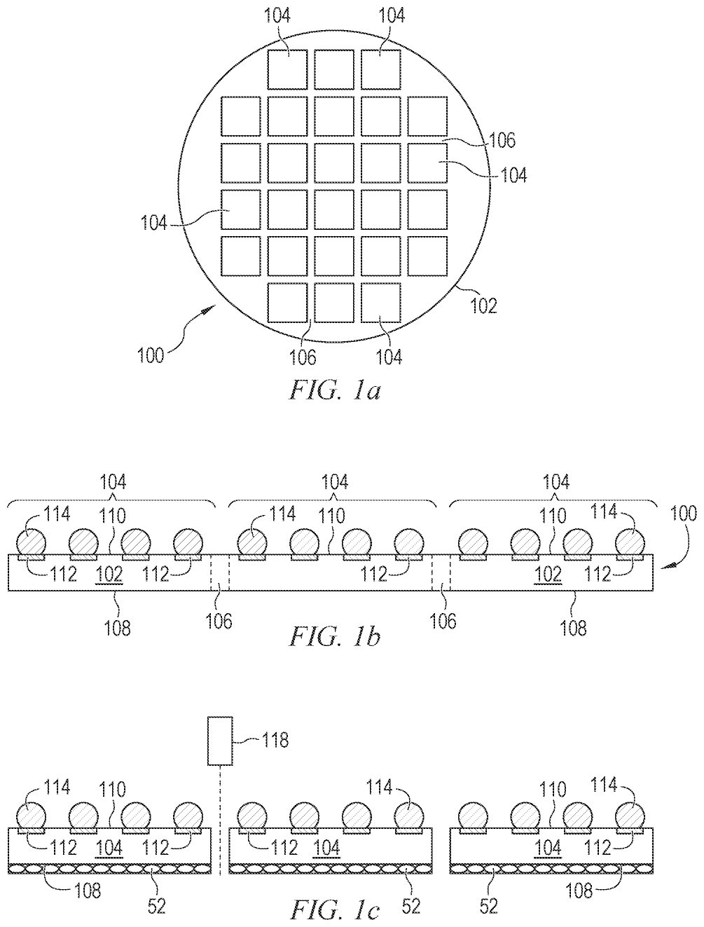

FIG. 1a shows a semiconductor wafer 100 with a base substrate material 102, such as silicon, germanium, aluminum phosphide, aluminum arsenide, gallium arsenide, gallium nitride, indium phosphide, silicon carbide, or other bulk material for structural support. A plurality of semiconductor die or components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm). Alternatively, wafer 100 can be a mold surface, organic or inorganic substrate, or target substrate suitable for graphene transfer.

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under bump metallization (UBM) having a wetting layer, barrier layer, and adhesive layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

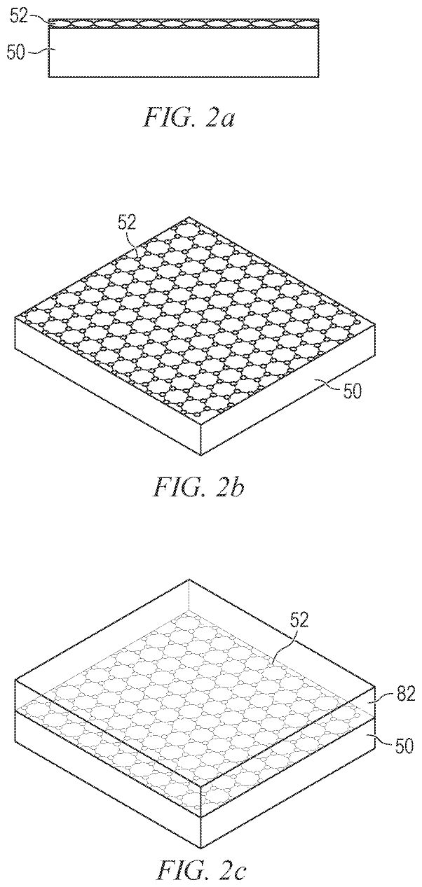

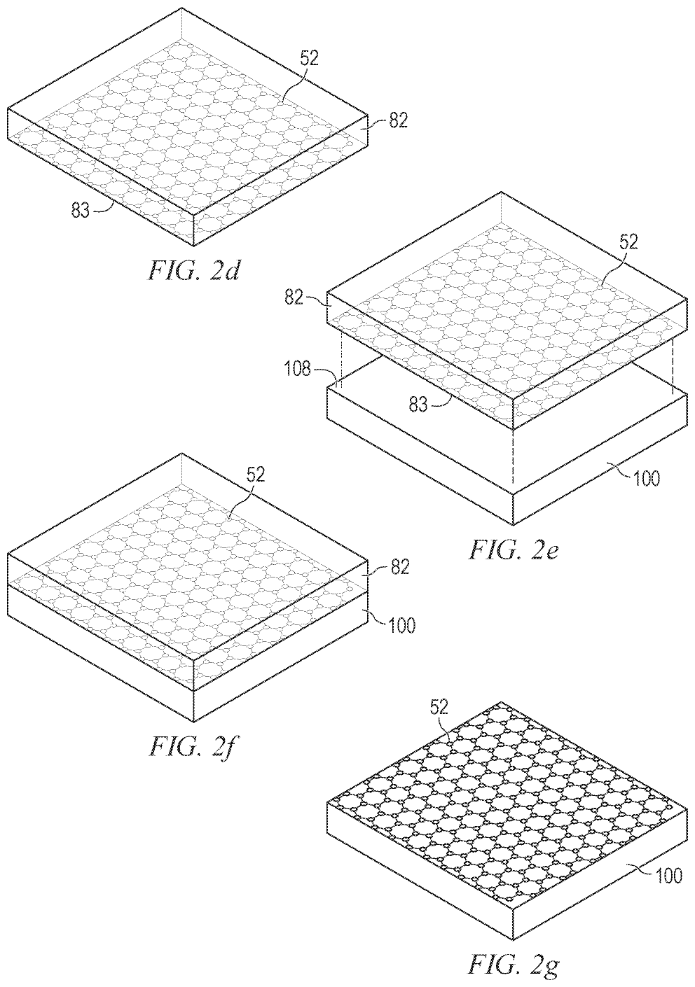

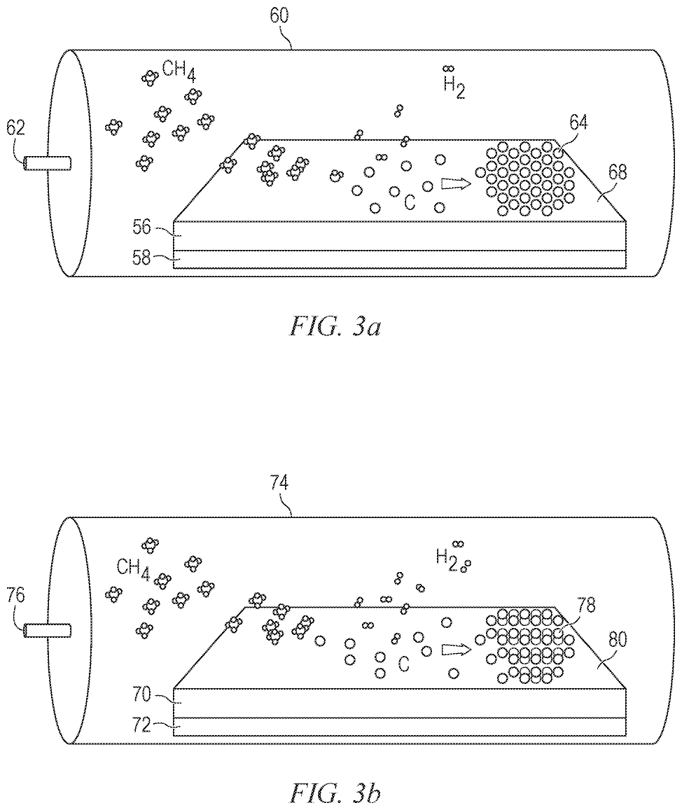

It has been discovered that graphene, in the proper configuration, can aid with heat dissipation of a semiconductor device. FIG. 2a illustrates substrate 50 and graphene layer 52 formed over the substrate. FIG. 2b is a perspective view of graphene layer 52 formed over substrate 50. Substrate 50 can be Cu, Ni, or other suitable metal or similar material. In one embodiment, substrate 50 is a Cu foil. Graphene layer 52 is an allotrope of carbon with one or more layers of carbon atoms each arranged in a two-dimensional (2D) honeycomb lattice. Graphene layer 52 can be formed by CVD. In one example, a Cu catalyst 56 on substrate 58 is placed in chamber 60, as shown in FIG. 3a. Substrate 58 can be silicon, polyimide film, polymer film, plastic film, or the similar material. Cu catalyst 56 is coated on substrate 58. Alternatively, catalyst 56 and substrate 58 can be one layer of Cu, Ni, Cu/Ni, or other suitable metal or metal foil. Chamber 60 is heated to 900-1080° C. and a gas mixture of CH₄/H₂/Ar is introduced into port 62 to initiate a CVD reaction. The carbon source decomposes in the high-temperature reaction chamber 60 as the CVD reaction separates the carbon atoms from the hydrogen atoms, leaving a single graphene layer 64 on surface 68 of Cu catalyst 56. The release of carbon atoms over the Cu catalyst substrate forms a continuous graphene layer. Once removed from chamber 60, graphene layer 52 on a Cu substrate 50, as in FIGS. 2a-2b, are realized.

In another example, a Ni catalyst 70 on substrate 72 is placed in chamber 74, as shown in FIG. 3b. Substrate 72 can be silicon, Pl film, polymer film, plastic film, or similar material. Ni catalyst 70 is coated on substrate 72. Alternatively, catalyst 70 and substrate 72 can be one layer of Cu, Ni, Cu/Ni, or other suitable metal or metal foil. Chamber 74 is heated to 900-1080° C. and a gas mixture of CH₄/H₂/Ar is introduced into port 76. The carbon source decomposes in the high-temperature reaction chamber 74 as the CVD reaction separates the carbon atoms from the hydrogen atoms, leaving multiple graphene layers 78 on surface 80 of Ni catalyst 70. Once removed from chamber 74, graphene layer 52 on a Ni substrate 50, as in FIGS. 2a-2b, is realized. Additional information related to forming graphene by CVD is disclosed in U.S. Pat. No. 8,535,553, and hereby incorporated by reference.

The properties of graphene are summarized in Table 1, as follows:

TABLE 1
Properties of graphene

| Parameter | | |
|---|---|---|
| Electronic mobility | 2 × 10⁵ | cm² V⁻¹ s⁻¹ |
| Current density | 10⁹ | A cm⁻¹ |
| Velocity of fermion (electron) | 10⁶ | m s⁻¹ |
| Thermal conductivity | 4000-5000 | W m⁻¹ K⁻¹ |
| Tensile strength | 1.5 | Tpa |
| Breaking strength | 42 | N m⁻¹ |
| Transparency | 97.7% | |
| Elastic limit | 20% | |
| Surface area | 2360 | m² g⁻¹ |

Returning to FIG. 2c, support layer 82 is formed or disposed over graphene layer 52 from FIGS. 2a-2b. Support layer 82 can be poly(methyl methacrylate) (PMMA), acrylic, acrylic glass, or other transparent thermoplastic. Support layer 82 can be applied as a coating. Graphene layer 52 adheres to support layer 82 by nature of the sticky PMMA material.

In FIG. 2d, substrate 50 is removed by an etching process, leaving graphene layer 52 adhering to the underside surface 83 of support layer 82. Graphene layer 52 and support layer 82 are rinsed with deionized water.

In FIG. 2e, semiconductor wafer 100 undergoes a grinding operation or chemical mechanical polish (CMP) to planarize back surface 108. Support layer 82 is placed over the planar back surface 108 of semiconductor wafer 100 from FIGS. 1a-1b with graphene layer 52 oriented toward the back surface of the wafer. Graphene layer 52 is brought into contact with back surface 108 of semiconductor wafer 100. FIG. 2f shows support layer 82 disposed on semiconductor wafer 100 with graphene layer 52 in contact with back surface 108 of the wafer. Semiconductor wafer 100 undergoes a baking process, e.g., 80-120° C. for 10 minutes to 1.0 hour, to adhere graphene layer 52 to back surface 108 of the wafer. An adhesive can be used to form or supplement the bond between graphene layer 52 and back surface 108.

In FIG. 2g, support layer 82 is removed by acetone or an etching process, leaving graphene layer 52 adhering to back surface 108 of semiconductor wafer 100. Graphene layer 52 and wafer 100 are rinsed with deionized water and dried with nitrogen. In one embodiment, graphene layer 52 has a thickness of 0.345 nanometers (nm) as a single layer or 1-5 nm as multiple layers.

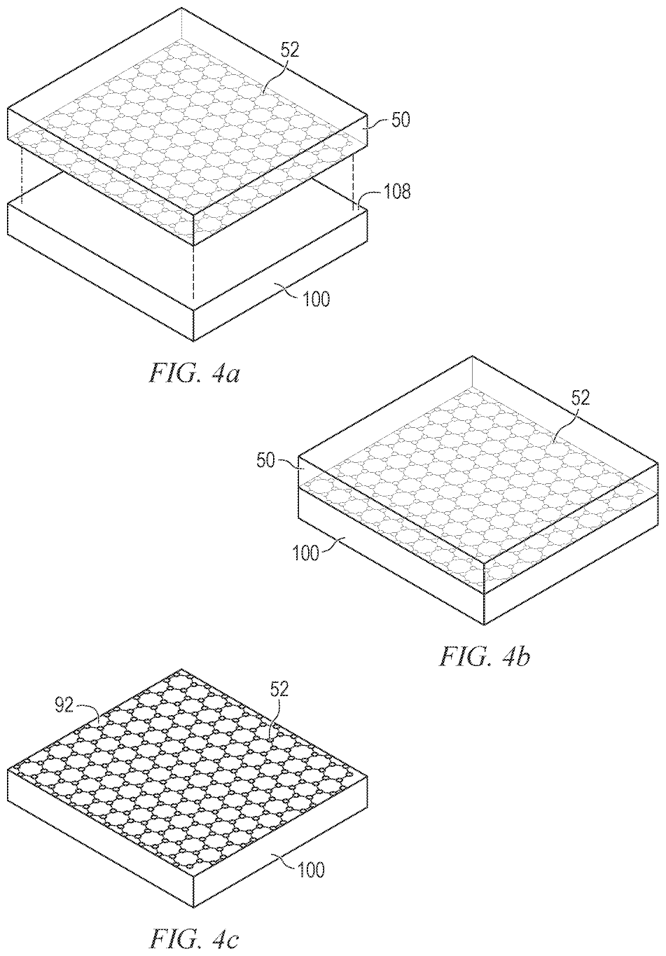

In another embodiment, continuing from FIG. 2b, semiconductor wafer 100 undergoes a grinding operation or CMP to planarize back surface 108. Substrate 50 and graphene layer 52 are placed over the planar back surface 108 of semiconductor wafer 100 from FIGS. 1a-1b with graphene layer 52 oriented toward the back surface of the wafer, as shown in FIG. 4a. Graphene layer 52 is brought into contact with back surface 108 of semiconductor wafer 100. FIG. 4b shows substrate 50 disposed on semiconductor wafer 100 with graphene layer 52 in contact with back surface 108 of the wafer. Semiconductor wafer 100 undergoes a baking process, e.g., 80-120° C. for 10 minutes to 1.0 hour, to adhere graphene layer 52 to back surface 108 of the wafer. An adhesive can be used to form or supplement the bond between graphene layer 52 and back surface 108. In FIG. 4c, substrate 50 is removed by an etching process, leaving graphene layer 52 adhering to back surface 108 of semiconductor wafer 100. Graphene layer 52 and back surface 108 are rinsed with deionized water and dried with nitrogen.

Returning to FIG. 1c, semiconductor wafer 100 with graphene layer 52 from FIG. 2g or FIG. 4c is singulated through saw street 106 using a saw blade or laser cutting tool 118 into individual semiconductor die 104 each with an associated graphene layer disposed on back surface 108. The individual semiconductor die 104 can be inspected and electrically tested for identification of known good die or unit (KGD/KGU) post singulation.

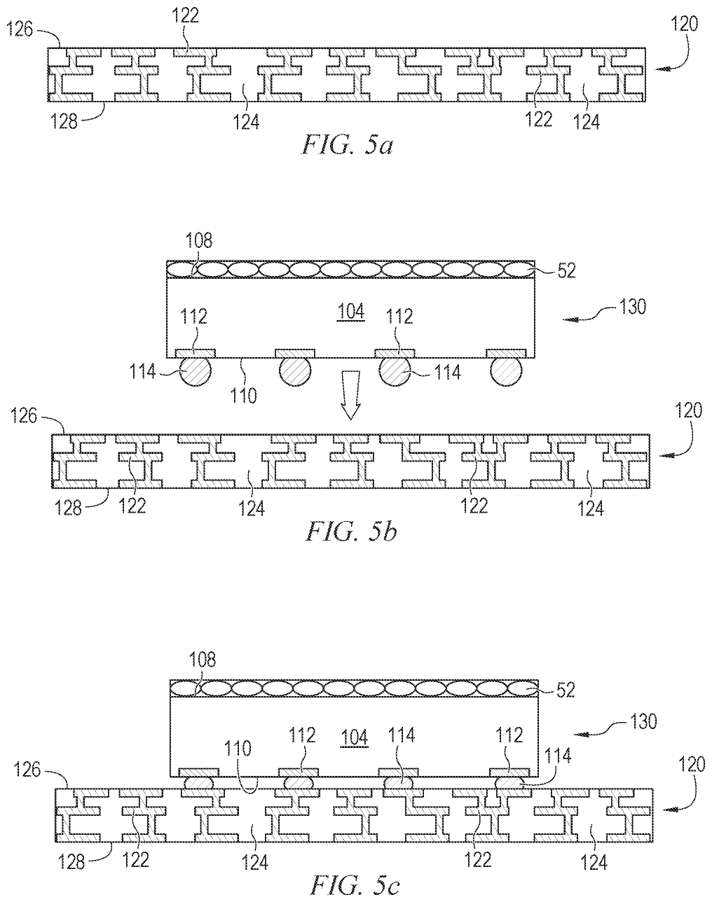

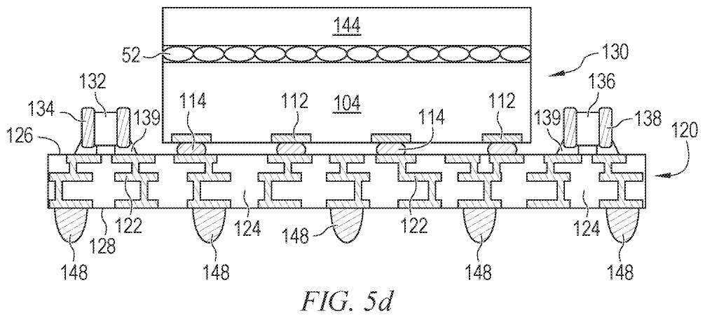

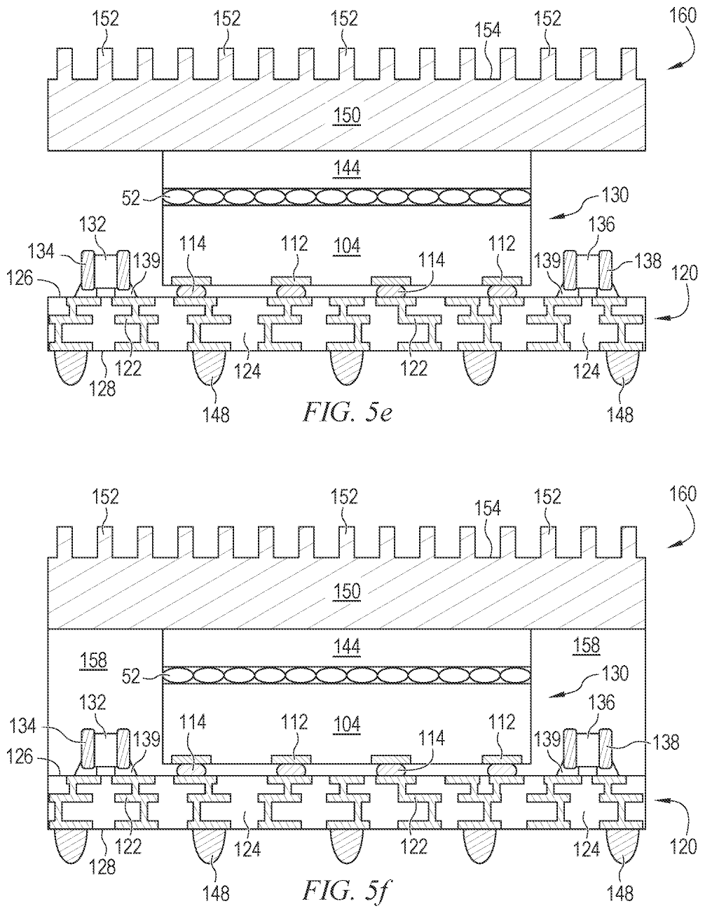

FIGS. 5a-5f illustrate a process of forming an SiP module with an electrical component and graphene layer for thermal dissipation. FIG. 5a shows a cross-sectional view of multi-layered interconnect substrate 120 including conductive layers 122 and insulating layer 124. Conductive layer 122 can be one or more layers of Al, Cu, Sn, Ni, Au, Ag, or other suitable electrically conductive material. Conductive layers can be formed using PVD, CVD, electrolytic plating, electroless plating process, or other suitable metal deposition process. Conductive layer 122 provides horizontal electrical interconnect across substrate 120 and vertical electrical interconnect between top surface 126 and bottom surface 128 of substrate 120. Portions of conductive layer 122 can be electrically common or electrically isolated depending on the design and function of semiconductor die 104 and other electrical components. Insulating layer 124 contains one or more layers of silicon dioxide (SiO2), silicon nitride (Si3N4), silicon oxynitride (SiON), tantalum pentoxide (Ta2O5), aluminum oxide (Al2O3), solder resist, polyimide, benzocyclobutene (BCB), polybenzoxazoles (PBO), and other material having similar insulating and structural properties. Insulating layer 124 provides isolation between conductive layers 122.

In FIG. 5b, electrical components 130 is disposed on surface 126 of interconnect substrate 120 and electrically and mechanically connected to conductive layers 122. Electrical component 130 is positioned over substrate 120 using a pick and place operation. For example, electrical component 130 can be semiconductor die 104 from FIG. 1c, with graphene layer 52 disposed on back surface 108 and active surface 110 and bumps 114 oriented toward surface 126 of substrate 120. Alternatively, electrical component 130 can include other semiconductor die, semiconductor packages, surface mount devices, RF components, discrete electrical devices, or IPDs, such as a diode, transistor, resistor, capacitor, and inductor. FIG. 5c illustrates electrical component 130, with graphene layer 52 disposed on back surface 108, electrically and mechanically connected to conductive layers 122 of substrate 120 with bumps 114.

In another embodiment, support layer 82 with graphene layer 52 from FIG. 2g remains after semiconductor wafer singulation in FIG. 1c. In this case, support layer 82 from FIG. 2g is removed after disposing electrical component 130 on substrate 120. Support layer 82 is removed by acetone or an etching process, leaving graphene layer 52 adhering to surface 108 of semiconductor wafer 100, as in FIG. 5c.

In FIG. 5d, electrical components 132 and 136 are disposed on surface 126 of substrate 120 with electrically conductive terminals 134 and 138 electrically and mechanically connected to conductive layers 122 of the substrate with solder or conductive paste 139. Electrical components 132 and 136 can be discrete electrical devices, or IPDs, such as a diode, transistor, resistor, capacitor, and inductor. Alternatively, electrical components 132 and 136 can include other semiconductor die, semiconductor packages, surface mount devices, or RF components.

Electrical components 130, 132, and 136 may contain features that are susceptible to or generate EMI, RFI, harmonic distortion, and inter-device interference. For example, electrical components 130, 132, and 136 provide the electrical characteristics needed for high-frequency and high power applications, such as resonators, high-pass filters, low-pass filters, band-pass filters, symmetric Hi-Q resonant transformers, and tuning capacitors. In another embodiment, electrical components 130, 132, and 136 contain digital circuits switching at a high frequency, which could interfere with the operation of IPDs in the SIP module. Electrical components 130, 132, and 136 operating at high speed and/or high power are known to generate significant heat and require proper thermal dissipation.

A thermal interface material (TIM) 144 is deposited on graphene layer 52. In one embodiment, TIM 144 is an adhesive with filler containing alumina, Al, aluminum zinc oxide, or other material having good heat transfer properties. Alternatively, TIM 144 can be a paste, film, solder, Ag, In, or Ag-In. If solder is used, the material should be wet on graphene layer 52.

An electrically conductive bump material is deposited over conductive layer 122 of surface 128 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 148. In one embodiment, bump 148 is formed over a UBM having a wetting layer, barrier layer, and adhesive layer. Bump 148 can also be compression bonded or thermocompression bonded to conductive layer 122. Bump 148 represents one type of interconnect structure that can be formed over conductive layer 122. The interconnect structure can also use bond wires, conductive paste, stud bump, micro bump, or other electrical interconnect.

In FIG. 5e, heat sink or heat spreader 150 is disposed over TIM 144 with an adhesive, or by nature of the adhesive property of the TIM. Heat sink 150 can be one or more layers of Al, Cu, Sn, Ni, Au, Ag, or other suitable thermally conductive material. Heat sink 150 dissipates heat generated by electrical components 130, 132, and 136, as transferred through graphene layer 52 and TIM 144 to the heat sink. Heat sink 150 may include extensions or tabs 152 extending vertical or perpendicular with respect to surface 154 of the heat sink. Extensions 152 provide additional surface area for heat dissipation.

As an option in FIG. 5f, an encapsulant or molding compound 158 is deposited over and around electrical components 130, 132, and 136 on surface 126 of substrate 120 using a paste printing, compressive molding, transfer molding, liquid encapsulant molding, vacuum lamination, spin coating, or other suitable applicator. Encapsulant 158 can be polymer composite material, such as epoxy resin with filler, epoxy acrylate with filler, or polymer with proper filler. Encapsulant 158 is non-conductive, provides structural support, and environmentally protects the semiconductor device from external elements and contaminants.

The combination of interconnect substrate 120, electrical components 130, 132, and 136, graphene layer 52, TIM 144, and heat sink 150 constitute SiP 160. Graphene layer 52, in combination with TIM 144, aids with the heat transfer capability of SiP 160, particularly between electrical components 130, 132, and 136, known to generate heat, and heat sink 150, useful to dissipate heat. Graphene layer 52 has a low moisture permeability and a high thermal conductivity of 4000-5000 W m⁻¹ K⁻¹, 10 times higher than Cu at room temperature. Since carbon also has a good solderability and wettability of solder paste, TIM 144 and heat sink 150 can be readily attached. Graphene layer 52 exhibits a high degree of flexibility and remains stable against warpage. Graphene layer 52 improves thermal conductivity, while lowering manufacturing cost.

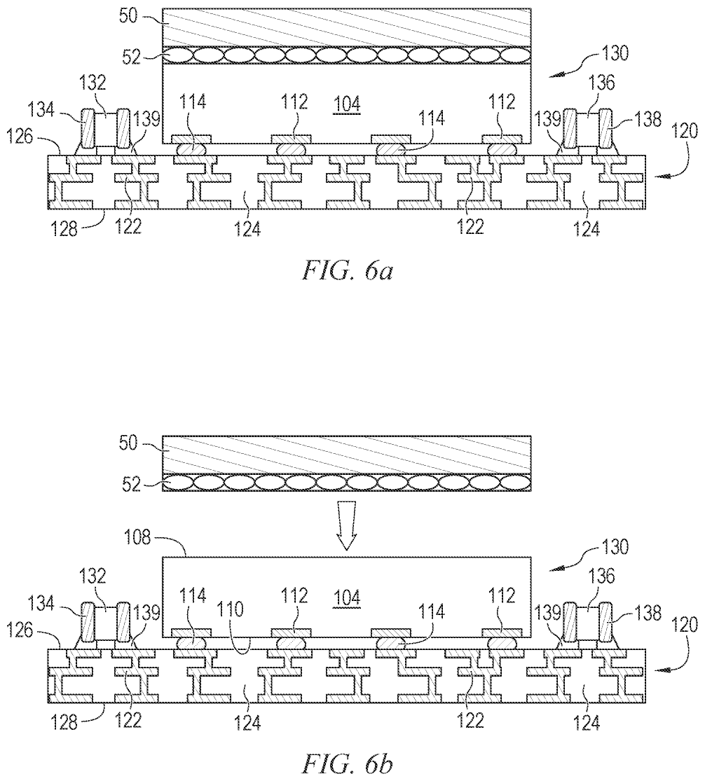

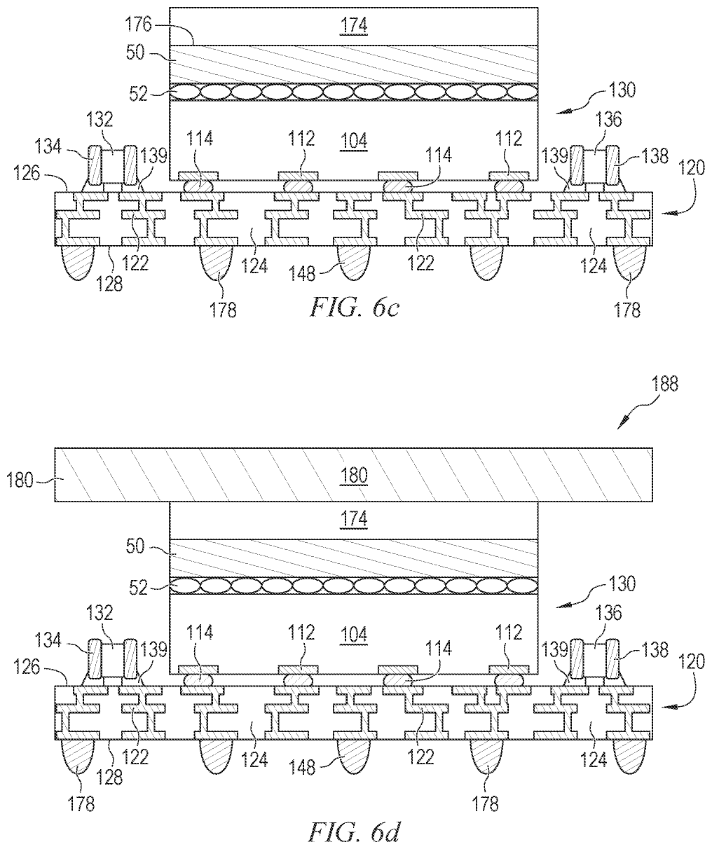

In another embodiment, continuing from FIG. 5a, electrical components 132 and 136 are disposed on substrate 120 with electrically conductive terminals 134 and 138 electrically and mechanically connected to conductive layers 122 of the substrate with solder or conductive paste 139, as shown in FIG. 6a. Elements having a similar function are assigned the same reference number in the figures. Dimensions as shown are not necessarily drawn to scale in the figures. In this case, semiconductor wafer 100 with substrate 50 and graphene layer 52 from FIG. 4b is singulated, similar to FIG. 1c. The singulated semiconductor die 104, with graphene layer 52 and substrate 50 attached to back surface 108, is disposed on surface 126 of substrate 120 with bumps 114 mechanically and electrically connected to conductive layer 122, similar to FIG. 5b-5c.

FIG. 6b shows an alternative approach in which semiconductor die 104 (without a graphene layer) is disposed on surface 126 of substrate 120 with bumps 114 mechanically and electrically connected to conductive layer 122, similar to FIG. 5b-5c. Substrate 50 with graphene layer 52 from FIG. 4a is singulated into die-size units and attached to back surface 108, as shown in FIG. 6b, again arriving at the configuration shown in FIG. 6a.

In FIG. 6c, TIM 174 is deposited on surface 176 of substrate 50. In one embodiment, TIM 174 is an adhesive with filler containing alumina, Al, aluminum zinc oxide, or other material having good heat transfer properties. Alternatively, TIM 174 can be a paste, film, solder, Ag, In, or Ag-In.

An electrically conductive bump material is deposited over conductive layer 122 on surface 128 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 178. In one embodiment, bump 178 is formed over a UBM having a wetting layer, barrier layer, and adhesive layer. Bump 178 can also be compression bonded or thermocompression bonded to conductive layer 122. Bump 178 represents one type of interconnect structure that can be formed over conductive layer 122. The interconnect structure can also use bond wires, conductive paste, stud bump, micro bump, or other electrical interconnect.

In FIG. 6d, heat sink or heat spreader 180 is disposed over TIM 144 with an adhesive, or by nature of the adhesive property of the TIM. Heat sink 180 can be one or more layers of Al, Cu, Sn, Ni, Au, Ag, or other suitable thermally conductive material. Heat sink 180 dissipates heat generated by electrical components 130, 132, and 136, as transferred through graphene substrate 50-52, and TIM 174 to the heat sink.

The combination of interconnect substrate 120, electrical components 130, 132, and 136, graphene substrate 50-52, TIM 174, and heat sink 180 constitute SiP 188. Graphene substrate 50-52, in combination with TIM 174, aids with the heat transfer capability of SiP 188, particularly between electrical components 130, 132, and 136, known to generate heat, and heat sink 180, useful to dissipate heat. Graphene substrate 50-52 has a low moisture permeability and a high thermal conductivity of 4000-5000 W m⁻¹ K⁻¹, 10 times higher than Cu at room temperature. Since carbon also has a good solderability and wettability of solder paste, TIM 174 and heat sink 180 can be readily attached. Graphene layer 52 exhibits a high degree of flexibility and remains stable against warpage. Graphene substrate 50-52 improves thermal conductivity for SiP 188, while lowering manufacturing cost.

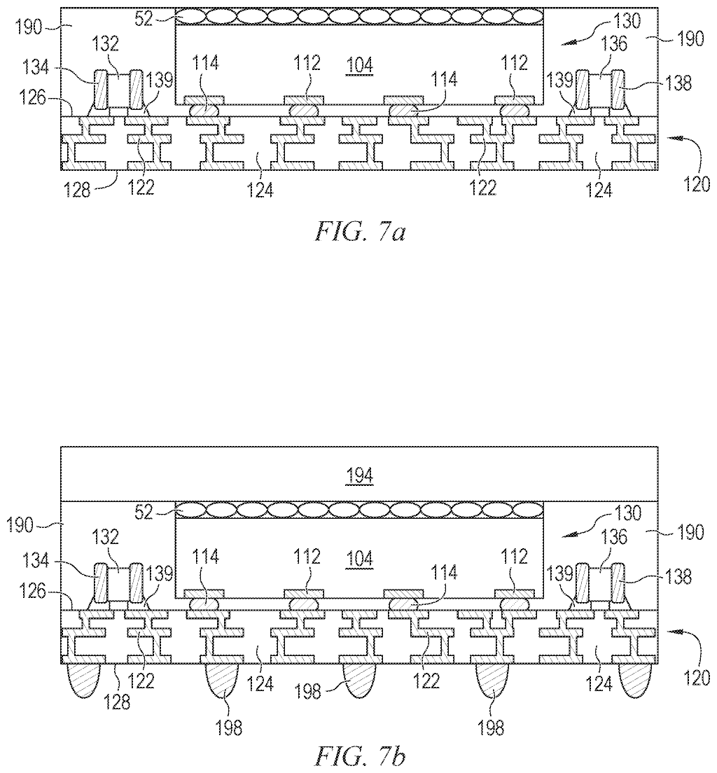

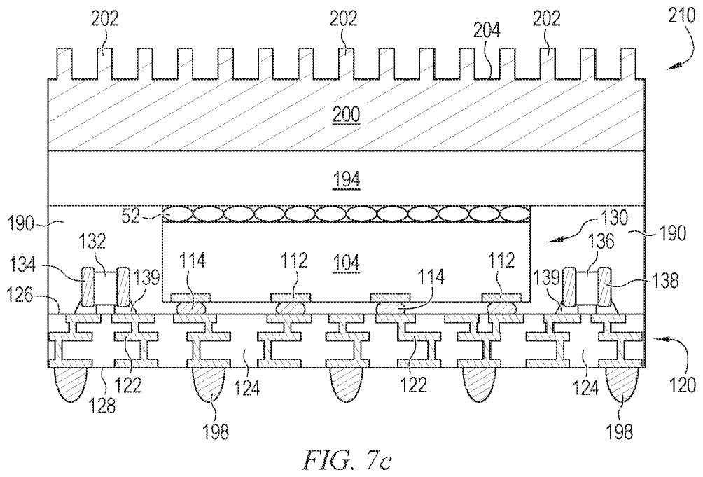

In another embodiment, continuing from FIG. 5c, an encapsulant or molding compound 190 is deposited over and around electrical components 130, 132, and 136 on substrate 120 using a paste printing, compressive molding, transfer molding, liquid encapsulant molding, vacuum lamination, spin coating, or other suitable applicator, as shown in FIG. 7a. Encapsulant 190 can be polymer composite material, such as epoxy resin with filler, epoxy acrylate with filler, or polymer with proper filler. Encapsulant 190 is non-conductive, provides structural support, and environmentally protects the semiconductor device from external elements and contaminants.

In FIG. 7b, TIM 194 is deposited on graphene layer 52 and encapsulant 190. In one embodiment, TIM 194 is an adhesive with filler containing alumina, Al, aluminum zinc oxide, or other material having good heat transfer properties. Alternatively, TIM 194 can be a paste, film, solder, Ag, In, or Ag-In. TIM 194 extends across encapsulant 190.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 198. In one embodiment, bump 198 is formed over a UBM having a wetting layer, barrier layer, and adhesive layer. Bump 198 can also be compression bonded or thermocompression bonded to conductive layer 122. Bump 198 represents one type of interconnect structure that can be formed over conductive layer 122. The interconnect structure can also use bond wires, conductive paste, stud bump, micro bump, or other electrical interconnect.

In FIG. 7c, heat sink or heat spreader 200 is disposed over TIM 194 with an adhesive, or by nature of the adhesive property of the TIM. Heat sink 200 can be one or more layers of Al, Cu, Sn, Ni, Au, Ag, or other suitable thermally conductive material. Heat sink 200 may include extensions or tabs 202 extending vertical or perpendicular with respect to surface 204 of the heat sink. Extensions 202 provide additional surface area for heat dissipation. Heat sink 200 extends across TIM 194 and encapsulant 190. Heat sink 200 dissipates heat generated by electrical components 130, 132, and 136, as transferred through graphene layer 52 and TIM 194 to the heat sink.

The combination of interconnect substrate 120, electrical components 130, 132, and 136, graphene layer 52, TIM 194, and heat sink 200 constitute SiP 210. Graphene layer 52, in combination with TIM 194, aids with the heat transfer capability of SiP 210 particularly between electrical components 130, 132, and 136, known to generate heat, and heat sink 200, useful to dissipate heat. Graphene layer 52 improves thermal conductivity for SiP 210, while lowering manufacturing cost.

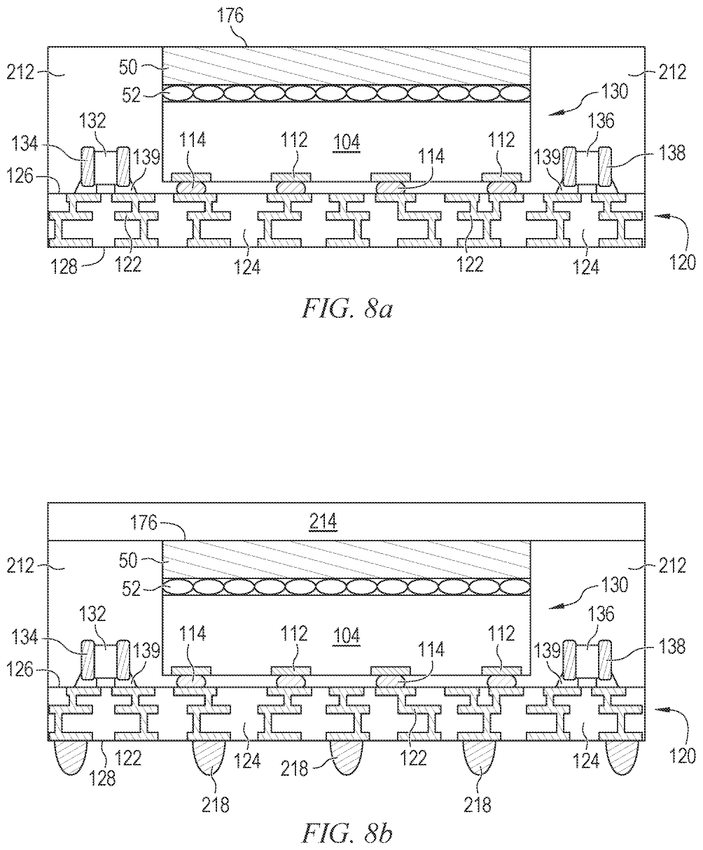

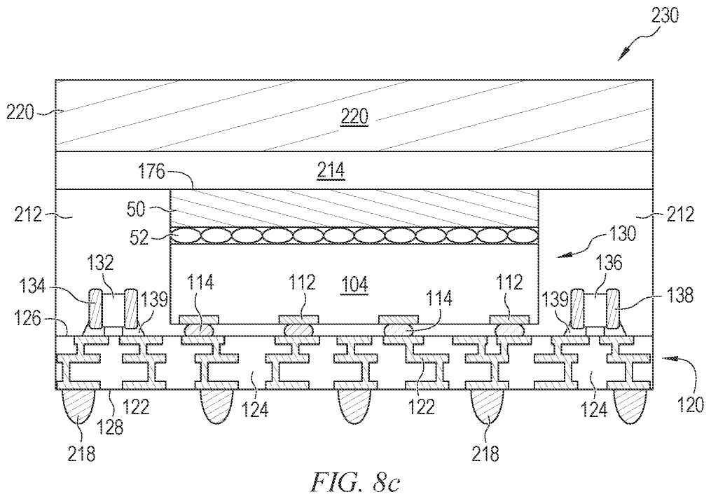

In another embodiment, continuing from FIG. 6a, an encapsulant or molding compound 212 is deposited over and around electrical components 130, 132, and 136 on surface 126 of substrate 120 using a paste printing, compressive molding, transfer molding, liquid encapsulant molding, vacuum lamination, spin coating, or other suitable applicator, as shown in FIG. 8a. Encapsulant 212 can be polymer composite material, such as epoxy resin with filler, epoxy acrylate with filler, or polymer with proper filler. Encapsulant 212 is non-conductive, provides structural support, and environmentally protects the semiconductor device from external elements and contaminants.

In FIG. 8b, TIM 214 is deposited on surface 176 of graphene substrate 50-52 and encapsulant 212. In one embodiment, TIM 214 is an adhesive with filler containing alumina, Al, aluminum zinc oxide, or other material having good heat transfer properties. Alternatively, TIM 214 can be a paste, film, solder, Ag, In, or Ag-In. TIM 214 extends across encapsulant 212.

An electrically conductive bump material is deposited over conductive layer 122 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to conductive layer 122 using a suitable attachment or bonding process. In one embodiment, the bump material is reflowed by heating the material above its melting point to form balls or bumps 218. In one embodiment, bump 218 is formed over a UBM having a wetting layer, barrier layer, and adhesive layer. Bump 218 can also be compression bonded or thermocompression bonded to conductive layer 122. Bump 218 represents one type of interconnect structure that can be formed over conductive layer 122. The interconnect structure can also use bond wires, conductive paste, stud bump, micro bump, or other electrical interconnect.

In FIG. 8c, heat sink or heat spreader 220 is disposed over TIM 214 with an adhesive, or by nature of the adhesive property of the TIM. Heat sink 220 can be one or more layers of Al, Cu, Sn, Ni, Au, Ag, or other suitable thermally conductive material. Heat sink 220 extends across TIM 214 and encapsulant 212. Heat sink 220 dissipates heat generated by electrical components 130, 132, and 136, as transferred through graphene substrate 50-52 and TIM 214 to the heat sink.

The combination of interconnect substrate 120, electrical components 130, 132, and 136, graphene substrate 50-52, TIM 214, and heat sink 220 constitute SiP 230. Graphene substrate 50-52, in combination with TIM 214, aids with the heat transfer capability of SiP 230, particularly between electrical components 130, 132, and 136, known to generate heat, and heat sink 220, useful to dissipate heat. Graphene substrate 50-52 improves thermal conductivity for SiP 230+, while lowering manufacturing cost.

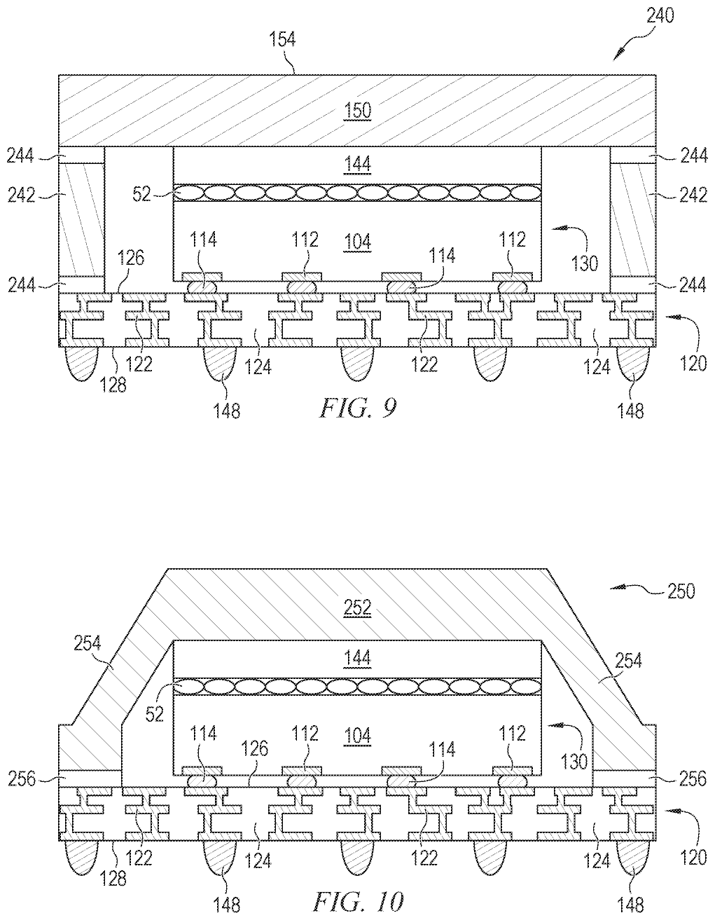

FIG. 9 illustrates another embodiment, similar to FIG. 5f, with SiP module 240 including vertical heat sink extensions or legs 242 extending from horizontal heat sink 150 to substrate 120. TIM 244 thermally connects heat sink 150 with heat sink legs 242 and substrate 120. Vertical heat sink legs 242 provide further heat dissipation from electronic components 130, 132, and 136, through graphene layer 52, to heat sink 150 and down heat sink legs 242 to substrate 120.

FIG. 10 illustrates another embodiment, similar to FIG. 5f, with SiP module 250 including heat sink 252 having angled heat sink extensions or legs 254 extending from horizontal heat sink 252 to substrate 120. TIM 256 thermally connects heat sink 252 and 254 with substrate 120. Angled heat sink legs 254 provide further heat dissipation from electronic components 130, 132, and 136, through graphene layer 52, to heat sink 252 and down angled heat sink legs 254 to substrate 120.

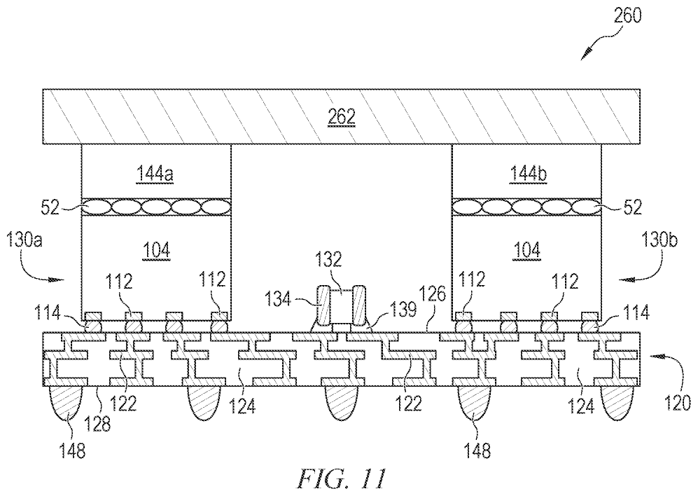

FIG. 11 illustrates another embodiment, similar to FIG. 5f, with SiP module 260 including heat sink 262 extending over multiple electrical components 130a and 130b each having graphene layer 52 and TIM 144a, 144b. Heat sink 262 provides further heat dissipation from electronic components 130a, 130b, and 132, through graphene layer 52.

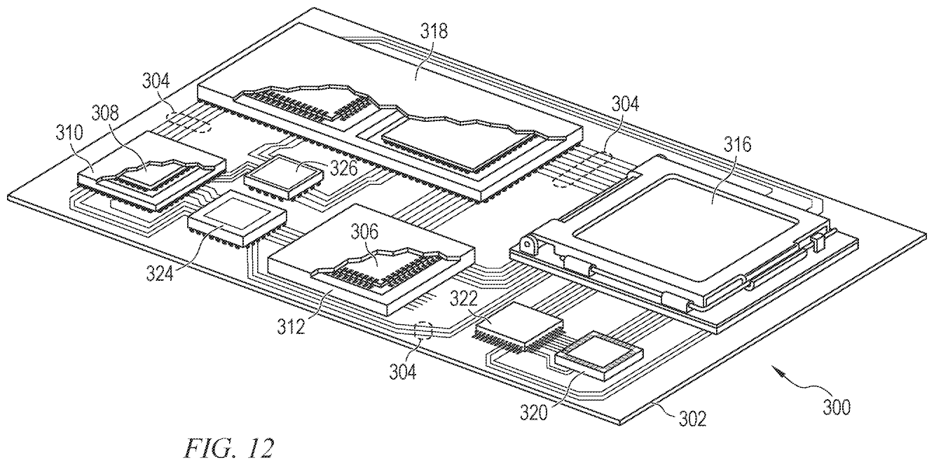

FIG. 12 illustrates electronic device 300 having a chip carrier substrate or PCB 302 with a plurality of semiconductor packages disposed on a surface of PCB 302, including SiP modules 160, 188, 210, 230, 240, 250, and 260. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASIC, logic circuits, analog circuits, RF circuits, discrete devices, or other semiconductor die or electrical components. Miniaturization and weight reduction are essential for the products to be accepted by the market. The distance between semiconductor devices may be decreased to achieve higher density.

In FIG. 12, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB. For the purpose of illustration, several types of first level packaging, including bond wire package 306 and flipchip 308, are shown on PCB 302. Additionally, several types of second level packaging, including ball grid array (BGA) 310, bump chip carrier (BCC) 312, land grid array (LGA) 316, multi-chip module (MCM) or SIP module 318, quad flat non-leaded package (QFN) 320, quad flat package 322, embedded wafer level ball grid array (eWLB) 324, and wafer level chip scale package (WLCSP) 326 are shown disposed on PCB 302. In one embodiment, eWLB 324 is a fan-out wafer level package (Fo-WLP) and WLCSP 326 is a fan-in wafer level package (Fi-WLP). Depending upon the system requirements, any combination of semiconductor packages, configured with any combination of first and second level packaging styles, as well as other electronic components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A semiconductor device, comprising:
a first substrate;
an electrical component disposed over the first substrate;
a graphene layer disposed over the electrical component; and
a heat sink disposed over the graphene substrate.

2. The semiconductor device of claim 1, further including a second substrate, wherein the graphene layer is disposed on the second substrate.

3. The semiconductor device of claim 2, wherein the second substrate includes copper.

4. The semiconductor device of claim 1, further including a thermal interface material disposed between the graphene layer and heat sink.

5. The semiconductor device of claim 1, further including an encapsulant deposited over the first substrate and around the electrical component.

6. The semiconductor device of claim 5, wherein the heat sink extends over the encapsulant.

7. A semiconductor device, comprising:
an electrical component; and
a graphene layer disposed over the electrical component.

8. The semiconductor device of claim 7, further including a substrate, wherein the graphene layer is disposed on the substrate.

9. The semiconductor device of claim 8, wherein the substrate includes copper.

10. The semiconductor device of claim 7, further including a heat sink disposed over the graphene substrate.

11. The semiconductor device of claim 10, further including a thermal interface material disposed between the graphene substrate and heat sink.

12. The semiconductor device of claim 7, further including an encapsulant deposited around the electrical component and graphene substrate.

13. The semiconductor device of claim 12, wherein the heat sink extends over the encapsulant.

14. A method of making a semiconductor device, comprising:
providing a first substrate;
disposing an electrical component over the first substrate;
disposing a graphene layer over the electrical component; and
disposing a heat sink over the graphene substrate.

15. The method of claim 14, further including disposing a second substrate, wherein the graphene layer is disposed on the second substrate.

16. The method of claim 15, wherein the second substrate includes copper.

17. The method of claim 14, further including disposing a thermal interface material between the graphene layer and heat sink.

18. The method of claim 14, further including depositing an encapsulant over the substrate and around the electrical component.

19. The method of claim 14, wherein the heat sink extends over the encapsulant.

20. A method of making a semiconductor device, comprising:
providing an electrical component; and
disposing a graphene layer over the electrical component.

21. The method of claim 20, further including disposing a second substrate, wherein the graphene layer is disposed on the second substrate.

22. The method of claim 21, wherein the second substrate includes copper.

23. The method of claim 20, further including disposing a thermal interface material between the graphene substrate and heat sink.

24. The method of claim 20, further including depositing an encapsulant around the electrical component and graphene layer.

25. The method of claim 24, wherein the heat sink extends over the encapsulant.
